(19) United States
(12) Patent Application Publication
(10) Pub. No.: US 2009/0114964 A1
(43) Pub. Date: May 7, 2009

(54) IMAGE SENSOR AND METHOD FOR MANUFACTURING THE SAME

(76) Inventor: Chang-Hun Han, Gangnam-gu (KR)

Correspondence Address: SHERR & VAUGHN, PLLC, 620 HERNDON PARKWAY, SUITE 200, HERNDON, VA, 20170, US

(21) Appl. No.: 12/258,417

(22) Filed: Oct. 26, 2008

(30) Foreign Application Priority Data
Nov. 5, 2007 (KR) 10-2007-0112172
Nov. 20, 2007 (KR) 10-2007-0118338

(51) Int. Cl. H01L 31/00; H01L 21/00

(52) U.S. Cl. 257/292; 438/98; 257/E21.001; 257/E31.001

(57) ABSTRACT

An image sensor includes a first substrate having a lower wiring line and electric circuitry formed therein, a bonding layer formed over the first substrate, a second substrate bonded to the first substrate via the bonding layer, a vertical-type photodiode formed in the second substrate, and a contact plug formed in the photodiode and the bonding layer and electrically connected to the lower wiring line.

The present application claims priority under 35 U.S.C. §119 to Korean Patent Application No. 10-2007-0112172 (filed on Nov. 5, 2007), which is hereby incorporated by reference in its entirety.

### BACKGROUND

In general, an image sensor is a semiconductor device converting an optical image into an electrical signal and is largely classified into a charge coupled device (CCD) and a complementary metal oxide silicon (CMOS) image sensor (CIS). The CMOS image sensor has a photodiode and a MOS transistor formed within a unit pixel and sequentially detects electrical signals of unit pixels using a switching method, thereby implementing an image. A CMOS image sensor may have a structure in which a photodiode is arranged horizontally relative to a transistor.

Although the disadvantages of the CCD image sensor were alleviated by such a horizontal-type CMOS image sensor, the horizontal-type CMOS image sensor still has problems. Particularly, in a horizontal-type CMOS image sensor, a photodiode and a transistor are horizontally fabricated adjacent to each other on and/or over a substrate. Accordingly, there is a need for an additional area for the photodiode. Consequently, problems arise because the fill factor area is decreased and the resolution quality is limited. Further, in horizontal-type CMOS image sensors, it is very difficult to optimize a process of fabricating a photodiode and a transistor simultaneously. In other words, in a rapid transistor process, a shallow junction is required for a low sheet resistance, but this shallow junction may not be suitable for the photodiode. Moreover, a horizontal-type CMOS image sensor may require an additional on-chip function to the image sensor. Accordingly, the size of a unit pixel has to be increased in order to maintain the sensitivity of the image sensor or an area for the photodiode has to be decreased in order to maintain the pixel size. However, if the pixel size increases, the resolution of the image sensor decreases. Further, a problem occurs because, if the area of the photodiode decreases, the sensitivity of the image sensor decreases.

### SUMMARY

Embodiments relate to an image sensor and a method of manufacturing the same which provide new integration of circuitry and a photodiode.

Embodiments relate to an image sensor and a method of manufacturing the same in which resolution and sensitivity can be maximized at the same time.

Embodiments relate to an image sensor and a method of manufacturing the same in which defects within a photodiode can be prevented while adopting a vertical-type photodiode.

Embodiments relate to an image sensor and a method of manufacturing the same which facilitates fabrication of an image sensor adopting a vertical-type photodiode.

An image sensor in accordance in accordance with embodiments may include at least one of the following: a first substrate in which a lower wiring line and circuitry are formed, a bonding layer formed on and/or over the first substrate, a crystalline semiconductor layer bonded to the first substrate while coming in contact with a bonding layer, a photodiode formed in the crystalline semiconductor layer, and a contact plug formed in the photodiode and the bonding layer and electrically connected to the lower wiring line.

An image sensor in accordance in accordance with embodiments may include at least one of the following: a first substrate having a lower wiring line and electric circuitry formed therein; a bonding layer formed over the first substrate; a crystalline semiconductor layer bonded to the first substrate via the bonding layer; a vertical-type photodiode formed in the crystalline semiconductor layer; and a contact plug formed in the photodiode and the bonding layer and electrically connected to the lower wiring line.

A method of manufacturing an image sensor in accordance with embodiments may include at least one of the following: preparing a first substrate in which a lower wiring line and circuitry are formed, and then forming a bonding layer on and/or over the first substrate, and then preparing a second substrate in which a photodiode is formed, and then bonding the second substrate and the first substrate together such that the photodiode is brought in contact with the bonding layer, and then removing a lower side of the bonded second substrate, thereby exposing the photodiode.

A method of manufacturing an image sensor in accordance with embodiments may include at least one of the following: providing a first substrate having a lower wiring line and electric circuitry formed therein; and then forming a bonding layer over the first substrate; and then providing a second substrate having a photodiode formed therein; and then performing a bonding process at the bonding layer to form an attachment between the second substrate and the first substrate; and then exposing the photodiode by removing a portion of the second substrate.

A method in accordance with embodiments may include at least one of the following: providing a first substrate having a lower wiring line and at least one transistor formed therein; and then providing a second substrate; and then forming an epitaxial layer in the second substrate; and then forming a hydrogen ion implantation layer at an interface between the second substrate and the epitaxial layer by implanting hydrogen ions in the second substrate; and then forming a photodiode in the epitaxial layer; and then forming a bond at an interface between the second substrate and the first substrate; and then performing an annealing process on second substrate to convert the hydrogen ion implantation layer to a hydrogen gas layer; and then removing a portion of the second substrate at the hydrogen gas layer to expose the photodiode; and then forming a contact pug electrically connected to the lower wiring line.

In accordance with embodiments, an image sensor and a method of manufacturing the same can obtain vertical-type integration of circuitry and a photodiode.

In accordance with embodiments, a photodiode is formed in a crystalline semiconductor layer while adopting a vertical-type photodiode disposed over circuitry. Accordingly, defects within the photodiode can be prevented. A bonding layer is formed on and/or over a first substrate such as a logic substrate including a lower wiring line. Accordingly, bonding with a crystalline semiconductor layer in which a photodiode is formed is secured. A contact may be formed connected to the lower wiring line, thereby maximizing the performance of the image sensor with excellent performance can be fabricated. Vertical-type integration of circuitry and a photodiode enables the fill factor to approach 100%. Moreover, maximized sensitivity in the same pixel size can be provided by the vertical-type integration and also a reduction in overall costs. Each unit pixel can implement a more complicated circuitry without a reduction in sensitivity. Additional on-chip circuitry that can be integrated maximizes the overall performance of the image sensor and also accomplish miniaturization and reduced manufacturing costs of a semiconductor device.

### DRAWINGS

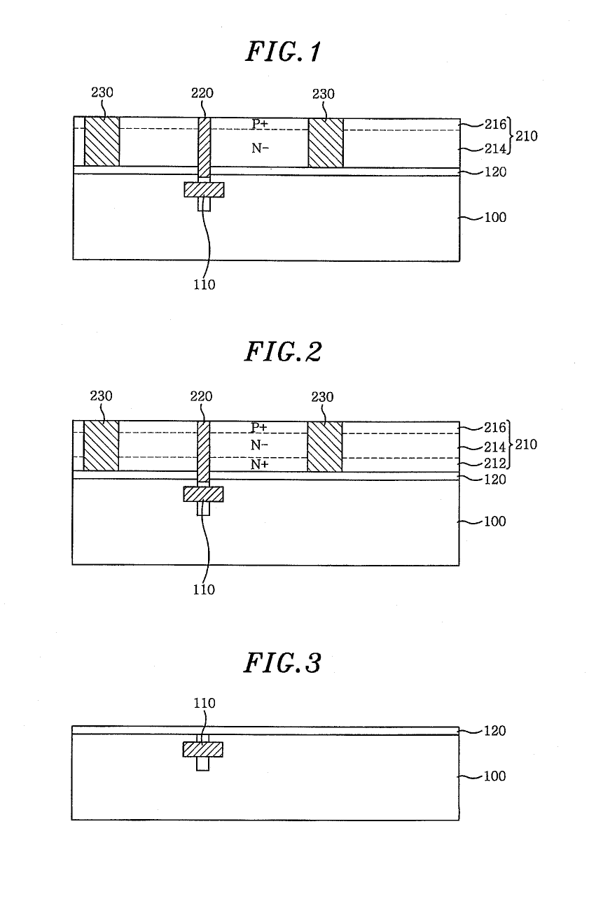

Example FIGS. 1 to 10 illustrate an image sensor and a method of manufacturing an image sensor in accordance with embodiments.

### DESCRIPTION

Hereinafter, an image sensor and a method of manufacturing the same in accordance with embodiments are described in detail with reference to the accompanying drawings.

In accordance with embodiments, description is given with reference to the drawings of a structure of a CMOS image sensor (CIS). However, embodiments are not limited to a CMOS image sensor, but can be applied to all image sensors such as a CCD image sensor.

As illustrated in example FIG. 1, an image sensor in accordance with embodiments may include first substrate 100 in which lower wiring line 110 and circuitry are formed. Bonding layer 120 is formed on and/or over first substrate 100 and crystalline semiconductor layer 210a may be bonded to first substrate 100 while coming in contact with bonding layer 120. Photodiode 210 may be formed in crystalline semiconductor layer 210a and contact plug 220 may be formed in photodiode 210 and bonding layer 120 in such a way as to form an electrical connection with lower wiring line 110.

In accordance with embodiments, photodiode 210 is formed in a crystalline semiconductor layer while adopting a vertical-type photodiode disposed over circuitry formed in substrate 100. Accordingly, defects in a photodiode can be prevented. Use of bonding layer 120 on and/or over first substrate 100 such as a logic substrate including lower wiring 110 enables bonding with a crystalline semiconductor layer in which photodiode 210 is formed. Contact plugs 220 connected to lower wiring line 110 is formed so that an image sensor with excellent performance can be easily fabricated.

In accordance with embodiments, the crystalline semiconductor layer can be a single crystalline semiconductor layer, but not limited thereto. The crystalline semiconductor layer can be a polycrystalline semiconductor layer. The bonding layer can have the same crystalline structure as that of the crystalline semiconductor layer, but is not limited thereto. The circuitry of first substrate 100 may include four transistors (4 Tr CIS) in the case of a CIS, or can also be applied to 1 Tr CIS, 3 Tr CIS, 5 Tr CIS or 1.5 Tr CIS (transistor sharing CIS), etc. Further, lower wiring line 110 formed in first substrate 100 can include lower metal and a lower plug. The upper portion of lower wiring line 110 can serve as a lower electrode of the photodiode.

Photodiode 210 can include a multi-layered structure such as a P-N structure. Photodiode 210 can include first conduction type conductive layer 214 formed in crystalline semiconductor layer 210a and second conduction type conductive layer 216 formed in crystalline semiconductor layer 210a on and/or over first conduction type conductive layer 214. For example, photodiode 210 can include low-concentration N-type conductive layer 214 formed in crystalline semiconductor layer 210a and high-concentration P-type conductive layer 216 formed in crystalline semiconductor layer 212 on and/or over low-concentration N-type conductive layer 214, but is not limited thereto. In other words, the first conduction type is not limited to an N-type, but may be a P-type.

As illustrated in example FIG. 2, photodiode 210 can further include high-concentration first conduction type conductive layer 212 formed in the crystalline semiconductor layer under first conduction type conductive layer 214. High-concentration first conduction type conductive layer 212 can be formed for an ohmic contact. Photodiode 210 can further include high-concentration N-type conductive layer 212 formed in the crystalline semiconductor layer under N-type conductive layer 214. Isolation layers 230 may be formed in crystalline semiconductor layer 210a adjacent lateral sides of contact plug 220. Isolation layers 230 may be formed having a shallow trench isolation (STI) structure in order to prevent crosstalk between pixels. An upper metal layer and a color filter may be formed on and/or over photodiode 210.

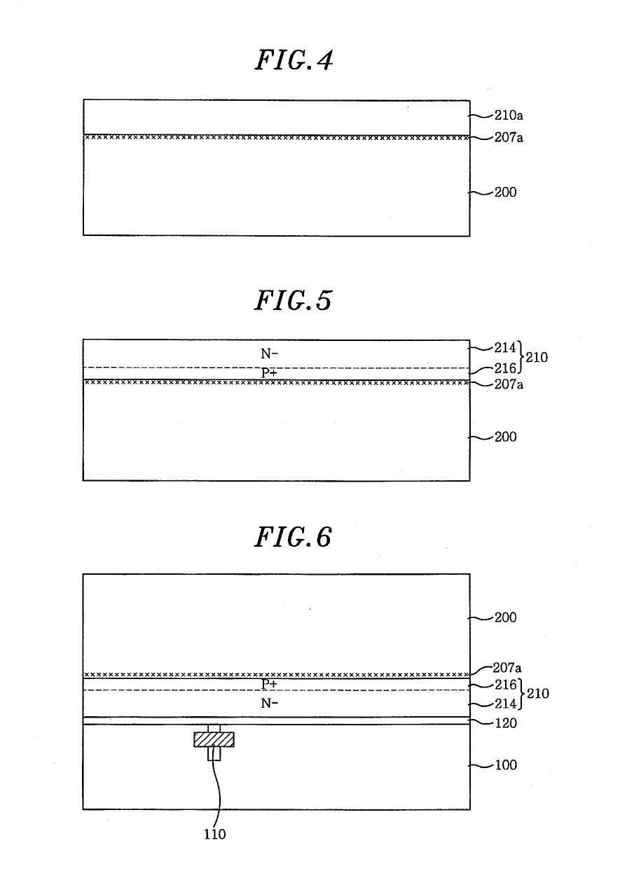

As illustrated in example FIG. 3, a method of manufacturing an image sensor in accordance with embodiments may include providing first substrate 100 having lower wiring line 110 and electric circuitry formed therein. The circuitry of first substrate 100 may include four transistors (4 Tr CIS) in the case of a CIS, or can also be applied to 1 Tr CIS, 3 Tr CIS, 5 Tr CIS or 1.5 Tr CIS (transistor sharing CIS), etc. Lower wiring line 110 formed in first substrate 100 can include a lower metal line and a lower plug connected thereto. Bonding layer 120 is formed on and/or over first substrate 100 including lower wiring line 110. Bonding layer 120 is formed of an oxide layer and functions to increase the bonding force between first substrate 100 and second substrate 200. However, the material of the bonding layer is not limited to an oxide layer. In a case in which isolation layers 230 are further formed in crystalline semiconductor layer 210a before bonding, bonding layer 120 of first substrate 100 and isolation layers 230 of second substrate 200 are formed from the same oxide layer material, thereby increasing the bonding force between the substrates. Bonding layer is formed on and/or over first substrate 100, that is, a logic substrate including lower wiring line 110, thereby ensuring bonding with the crystalline semiconductor layer in which the photodiode is formed. Subsequently, a contact connected to the lower wiring line is formed, so that an image sensor with excellent performance can be fabricated easily.

As illustrated in example FIGS. 4 and 5, a photodiode is formed on a crystalline semiconductor layer. As illustrated in example FIGS. 4 and 5, an epitaxial layer such as crystalline semiconductor layer 210a is formed in second substrate 200 by implanting hydrogen ions before the bonding of the substrates so as to remove a lower side of second substrate 200. Annealing is then performed after the bonding. However, embodiments are not limited to the above example. A buried insulating layer, such as silicon-on-insulator (SOI), can be employed as crystalline semiconductor layer 210a. As illustrated in example FIG. 4, crystalline semiconductor layer 210a is formed on and/or over second substrate 200 by an epitaxial method. Next, hydrogen ions are implanted in the boundary between second substrate 200 and crystalline semiconductor layer 210a, thus forming hydrogen ion implantation layer 207a.

As illustrated in example FIG. 5, photodiode 210 is then formed in crystalline semiconductor layer 210a through ion implantation. For example, second conduction type conductive layer 216 can be formed on and/or over a lower side of crystalline semiconductor layer 210a. For example, high concentration P-type conductive layer 216 can be formed on and/or over the lower side of crystalline semiconductor layer 210a by implanting ions into the entire surface of second substrate 200 using a blanket without a mask. First conduction type conductive layer 214 is ten formed on and/or over second conduction type conductive layer 216. For example, low concentration N-type conductive layer 214 can be formed on and/or over second conduction type conductive layer 216 by implanting ions into the entire surface of second substrate 200 using a blanket without a mask.

As illustrated in example FIG. 2, high-concentration first conduction type conductive layer 212 may be formed on and/or over first conduction type conductive layer 214. For example, high-concentration N-type conductive layer 212 can be formed on and/or over first conduction type conductive layer 214 by implanting ions into the entire surface of second substrate 200 using a blanket without a mask.

In a case in which isolation layers 230 are further formed in crystalline semiconductor layer 210a before bonding, the bonding force between bonding layer 120 of first substrate 100 and isolation layers 230 of second substrate 200 can be increased because they are made of the same oxide layer material. However, isolation layers 230 can also be formed even after bonding.

As illustrated in example FIG. 6, a bonding process is then performed so that second substrate 200 and first substrate 100 are bonded together such that photodiode 210 of second substrate 200 contacts bonding layer 120 of first substrate 100. For example, first substrate 100 and second substrate 200 can be bonded together using plasma activation after they are brought in contact with each other, but embodiments are not limited thereto.

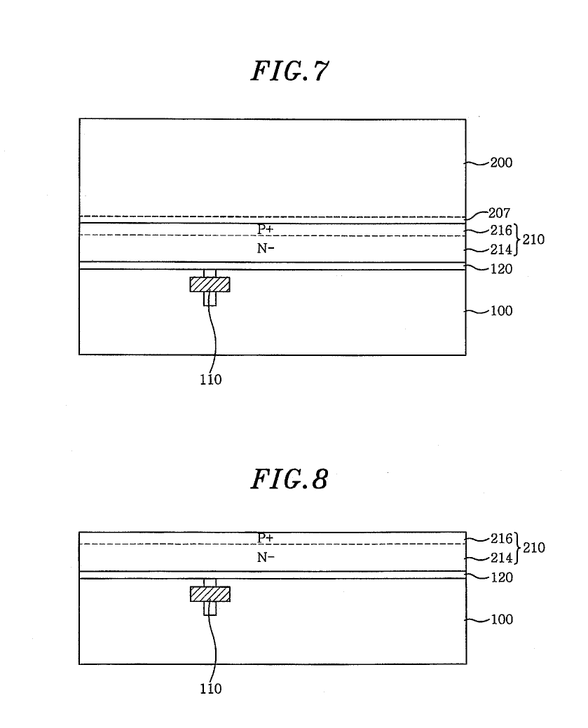

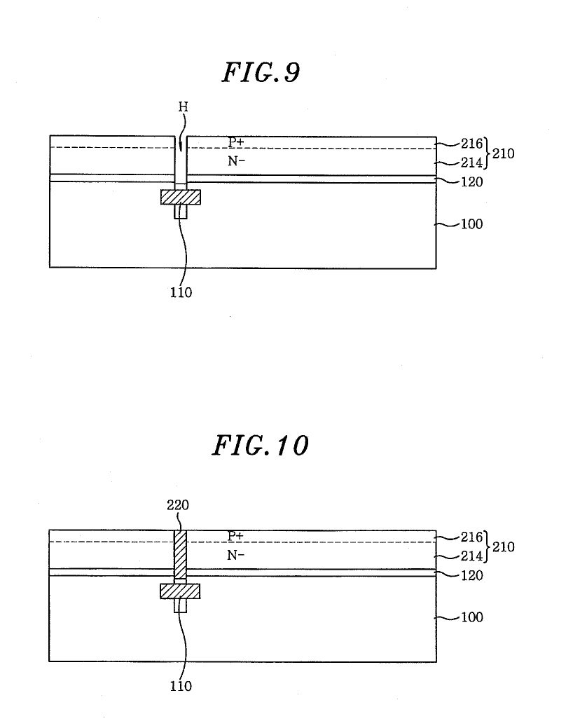

As illustrated in example FIG. 7, an annealing process is then performed on second substrate 200, so hydrogen ion implantation layer 207a changes phases to hydrogen gas layer 207. As illustrated in example FIG. 8, a side of second substrate 200 is removed at hydrogen gas layer 207 to expose photodiode 210. In the case in which isolation layers 230 are formed after the bonding process, isolation layers 230 can be formed after photodiode 210 is exposed. As illustrated in example FIG. 9, photodiode 210 and bonding layer 120 are selectively etched to thereby form contact hole H through which lower wiring line 110 is exposed. As illustrated in example FIG. 10, contact plug 220 coupled to exposed lower wiring line 110 is formed in contact hole H. Contact plug 220 can be formed using at least one of tungsten (W), titanium (Ti), titanium nitride (TiN) and aluminum (Al). Thereafter, an upper metal layer can be formed on and/or over photodiode 210 and passivation process can then be performed. A color filter can then be further formed on and/or over photodiode 210 and then a microlens or microlens array can also be formed on and/or over the color filter.

In accordance with embodiments, the method of manufacturing the image sensor includes a photodiode formed in a crystalline semiconductor layer while adopting a vertical-type photodiode structure in which the photodiode is placed on and/or over circuitry. Accordingly, defects within a photodiode can be prevented. Furthermore, in accordance with embodiments, a bonding layer is formed on and/or over a first substrate such as a logic substrate including a lower wiring line, thereby securing bonding with a crystalline semiconductor layer in which a photodiode is formed. A contact connected to the lower wiring line is then formed so that an image sensor with excellent performance can be fabricated easily.

Although embodiments have been described herein, it should be understood that numerous other modifications and embodiments can be devised by those skilled in the art that will fall within the spirit and scope of the principles of this disclosure. More particularly, various variations and modifications are possible in the component parts and/or arrangements of the subject combination arrangement within the scope of the disclosure, the drawings and the appended claims. In addition to variations and modifications in the component parts and/or arrangements, alternative uses will also be apparent to those skilled in the art.

What is claimed is:

1. An image sensor comprising:
a first substrate having a lower wiring line and electric circuitry formed therein;
a bonding layer formed over the first substrate;
a second substrate bonded to the first substrate via the bonding layer;
a vertical-type photodiode formed in the second substrate; and
a contact plug formed in the photodiode and the bonding layer and electrically connected to the lower wiring line.

2. The image sensor of claim 1, wherein the second substrate comprises an epitaxial layer.

3. The image sensor of claim 2, wherein the epitaxial layer comprises a crystalline semiconductor layer.

4. The image sensor of claim 3, wherein the photodiode comprises:
a first conduction type conductive layer formed in the crystalline semiconductor layer; and
a second conduction type conductive layer formed in the crystalline semiconductor layer over and contacting the first conduction type conductive layer.

5. The image sensor of claim 1, wherein the photodiode comprises:
a first conduction type conductive layer formed in the crystalline semiconductor layer;
a second conduction type conductive layer formed in the crystalline semiconductor layer over and contacting the first conduction type conductive layer; and
a high concentration first conduction type conductive layer formed in the crystalline semiconductor layer over and contacting the first conduction type conductive layer.

6. The image sensor of claim 1, wherein the contact plug is formed using at least one of tungsten (W), titanium (Ti), titanium nitride (TiN) and aluminum (Al).

7. The image sensor of claim 1, wherein the electric circuitry comprises at least one transistor.

8. A method of manufacturing an image sensor comprising:
providing a first substrate having a lower wiring line and electric circuitry formed therein; and then
forming a bonding layer over the first substrate; and then
providing a second substrate having a photodiode formed therein; and then
performing a bonding process at the bonding layer to form an attachment between the second substrate and the first substrate; and then
exposing the photodiode by removing a portion of the second substrate.

9. The method of claim 8, further comprising, after exposing the photodiode:
forming a contact hole to expose the lower wiring line by selectively etching the photodiode and the bonding layer; and then
forming a contact plug in the contact hole and connected to the lower wiring line.

10. The method of claim 9, wherein providing the second substrate comprises:
forming a crystalline semiconductor layer over the second substrate; and then
forming the photodiode in the crystalline semiconductor layer.

11. The method of claim 10, wherein providing the second substrate comprises implanting hydrogen ions into a boundary of the second substrate and the crystalline semiconductor layer.

12. The method of claim 11, wherein the bonding layer comprises an oxide layer.

13. The method of claim 8, wherein the bonding process comprises plasma activation.

14. A method comprising:
providing a first substrate having a lower wiring line and at least one transistor formed therein; and then
providing a second substrate; and then
forming an epitaxial layer in the second substrate; and then
forming a hydrogen ion implantation layer at an interface between the second substrate and the epitaxial layer by implanting hydrogen ions in the second substrate; and then
forming a photodiode in the epitaxial layer; and then
forming a bond at an interface between the second substrate and the first substrate; and then
performing an annealing process on second substrate to convert the hydrogen ion implantation layer to a hydrogen gas layer; and then
removing a portion of the second substrate at the hydrogen gas layer to expose the photodiode; and then
forming a contact pug electrically connected to the lower wiring line.

15. The method of claim 14, wherein forming the bond at an interface between the second substrate and the first substrate comprises:
forming a bonding layer over and contacting the first substrate including the lower wiring line after providing the first substrate; and then
performing a plasma activation process.

16. The method of claim 15, wherein forming the contact plug comprises:
forming a contact hole exposing the lower wiring line by etching the photodiode and the bonding layer; and then
forming a metal layer in the contact hole and contacting the lower wiring line.

17. The method of claim 16, wherein forming the metal layer comprises forming at least one of tungsten (W), titanium (Ti), titanium nitride (TiN) and aluminum (Al) in the contact hole.

18. The method of claim 14, wherein forming the photodiode comprises:
forming a second conduction type conductive layer over the hydrogen ion implantation layer; and then
forming a first conduction type conductive layer over and contacting the second conduction type conductive layer.

19. The method of claim 18, wherein forming the photodiode further comprises:
forming a high-concentration first conduction type conductive layer over and contacting the first conduction type conductive layer.

20. The method of claim 14, further comprising forming shallow trench isolation layers in the epitaxial layer before performing the bonding process.
